(19) United States
(12) Patent Application Publication
(10) Pub. No.: US 2021/0335824 A1
(43) Pub. Date: Oct. 28, 2021

(54) TFT ARRAY SUBSTRATE AND DISPLAY PANEL THEREOF

(71) Applicant: TCL China Star Optoelectronics Technology Co., LTD., Shenzhen, Guangdong (CN)

(72) Inventor: Jing LIU, Shenzhen (CN)

(21) Appl. No.: 16/617,567

(22) PCT Filed: Oct. 17, 2019
(86) PCT No.: PCT/CN2019/111630

§ 371 Date: Nov. 27, 2019

(30) Foreign Application Priority Data
Aug. 9, 2019 (CN) 201910732658.4

(51) Int. Cl. H01L 27/12; H01L 29/786

(52) U.S. Cl. CPC H01L 27/124; H01L 29/7869; H01L 27/1225

(57) ABSTRACT

A thin-film transistor (TFT) array substrate includes a substrate layer and a metal layer disposed on the substrate layer. The metal layer includes a first metal layer and a second metal layer disposed on the first metal layer. The first metal layer includes a main body portion and a tail portion. The main body portion of the first metal layer is disposed corresponding to the second metal layer in an upper direction, and the tail portion of the first metal layer is disposed on an end of the main body portion of the first metal layer and extends outwardly from the second metal layer. The TFT array substrate using a novel metal layer structure to effectively improve a situation that light leakage occurred at the metal layer structure of an array substrate in a dark state, and thus to increase product contrast.

### BACKGROUND OF INVENTION

### 1. Field of Invention

The present invention relates to a technical field of displays, and particularly to, a thin-film transistor (TFT) array substrate and a display panel thereof.

### 2. Related Art

With ever-changing flat panel display technology, industries continue to launch flat panel displays in better display performance and being lighter as well, such as liquid crystal displays, organic light-emitting diode (OLED) displays, and the like. Although these flat panel displays differ in specific structure due to different light-emitting principles, they all have a common component: a thin-film transistor (TFT) array substrate.

The TFT array substrate is an important component of the display driving part, and is a key component for realizing normal display functions of the display. A metal layer is often disposed on the TFT array substrate and is configured to constitute electronic components of functional circuits and to transmit data signals.

In addition, with advancement of information technology, flat panel displays are constantly moving toward large-scale. As a size of the flat panel displays increases, higher requirements are also placed on display quality of displayed images and pictures. There is also a growing demand for contrast of the flat panel displays.

However, after the survey, it was found that many display products on the market have a problem of insufficient contrast to a different degree. Based on theoretical and experimental analysis, it is found that a main reason is that light leakage occurred at intersections of metal layers of the array substrate in a dark state.

Therefore, it is imperative to develop a novel TFT array substrate to overcome the problem existing in prior art.

### SUMMARY OF INVENTION

The present invention provides a thin-film transistor (TFT) array substrate using a novel metal layer structure to effectively improve a situation that light leakage occurred at the metal layer structure of an array substrate in a dark state, thereby increasing product contrast.

The present invention provides technical solutions as follows:

A thin-film transistor (TFT) array substrate comprises a substrate layer and a metal layer disposed on the substrate layer. The metal layer comprises a first metal layer and a second metal layer disposed on the first metal layer; wherein the first metal layer comprises a main body portion and a tail portion. The main body portion of the first metal layer is disposed corresponding to the second metal layer in an upper direction, and the tail portion of the first metal layer is disposed on an end of the main body portion of the first metal layer and extends outwardly from the second metal layer. That is, the second metal layer covers the main body portion of the first metal layer in a downward direction, but the tail portion of the first metal layer is not covered by the second metal layer and is exposed to the second metal layer.

Further, in a different embodiment, the tail portion of the first metal layer comprises a first tail portion and a second tail portion disposed on two ends of the main body portion, respectively. Specifically, the first tail portion and the second tail portion may be symmetrically disposed, but are not limited thereto.

Further, in a different embodiment, the first metal layer is made of a first material and the second metal layer is made of a second material.

Further, in a different embodiment, the first metal layer is preferably made of metal molybdenum (Mo) or an alloy of metal molybdenum. For example, it is a binary alloy of metal molybdenum or a ternary alloy that may vary according to specific needs, and is not limited thereto.

Further, in a different embodiment, the second metal layer is made of aluminum metal or copper metal.

Further, in a different embodiment, the first metal layer has a thickness greater than 0 and less than or equal to 1000 angstroms.

Further, in a different embodiment, the second metal layer has a thickness greater than 0 and less than or equal to 8000 angstroms.

Further, in a different embodiment, the first metal layer is configured as a metal barrier layer, and the second metal layer is configured as a metal electrode layer.

Further, in a different embodiment, a third metal layer is further disposed on the second metal layer, wherein the first metal layer and the third metal layer are configured as a barrier metal layer, and the second metal layer configured as an electrode metal layer is sandwiched between the first metal layer and the third metal layer, wherein the first metal layer comprise the main body portion and the tail portion.

Preferably, the metal layer is a source/drain layer, wherein the first metal layer disposed below the electrode metal layer comprises a tail portion extending outward from the second metal layer, and the third metal layer disposed on the second metal layer is not configured with a tail portion extending outward from the source/drain layer.

Further, in a different embodiment, the metal layer is embodied as a gate layer (i.e. a gate electrode), a gate line, a gate pad, a data line, a data pad, a source metal layer, or a drain metal layer, and may vary according to specific needs, but is not limited thereto. Furthermore, the metal layer as mentioned above is not limited to a two-layered stacked metal layer structure, and may be a three-layered stacked metal layer structure, that may vary according to specific needs, and is not limited thereto.

Further, in a different embodiment, the tail portion of the first metal layer has a length greater than 0 and less than or equal to 0.25 microns (um).

Further, in a different embodiment, the metal layer is a gate layer, wherein the tail portion of the first metal layer has a length between 0.05 um and 0.25 um.

Further, in a different embodiment, the metal layer is a gate layer comprising a side portion disposed at an inclined angle between 25 and 50 degrees.

Further, in a different embodiment, the metal layer is a source/drain layer, wherein the tail portion of the first metal layer has a length greater than 0 and less than or equal to 0.10 um.

Further, in a different embodiment, the metal layer is a source/drain layer comprising a side portion disposed at an inclined angle between 50 and 90 degrees.

Further, in a different embodiment, an insulating layer is disposed on the metal layer, and an active layer is disposed on the insulating layer, wherein the active layer is preferably an indium gallium zinc oxide (IGZO) layer.

Further, in a different embodiment, an insulating layer is disposed on the metal layer, and an active layer is disposed on the insulating layer, wherein the active layer is preferably an amorphous silicon layer.

Further, in a different embodiment, the insulating layer may be a single-layered structure or a multi-layered stacked structure, for example, such as a two-layered stacked structure or a three-layered stacked structure, that may vary according to specific needs, and is not limited thereto.

Further, in another aspect, the present invention provides a display panel comprising a thin-film transistor (TFT) array substrate the same as the TFT array substrate of the aforementioned embodiments of the present invention.

The present invention provides a TFT array substrate configured with a metal layer including a barrier metal layer and an electrode metal layer, wherein the barrier metal layer includes tail portions having a specific length, and the electrode metal layer includes side portions formed at an inclined angle in a specific range, so that an entire structure of the metal layer is formed into a specific configuration, thereby effectively improving a situation that light leakage occurred at the metal layer structure of the array substrate in a dark state, and increasing product contrast.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a schematic structural view of a thin-film transistor (TFT) array substrate of an embodiment of the present invention.

FIG. 2 is a schematic structural view of a TFT array substrate of another embodiment of the present invention.

FIG. 3 is a schematic structural view of a TFT array substrate of another embodiment of the present invention.

FIG. 4 is a schematic structural view of a TFT array substrate of another embodiment of the present invention.

FIG. 5 is a schematic structural view of a TFT array substrate of another embodiment of the present invention.

### DESCRIPTION OF PREFERRED EMBODIMENTS

The technical solutions of a thin-film transistor (TFT) array substrate and a display panel thereof according to the present invention will be further described in detail below with reference to the accompanying drawings and embodiments.

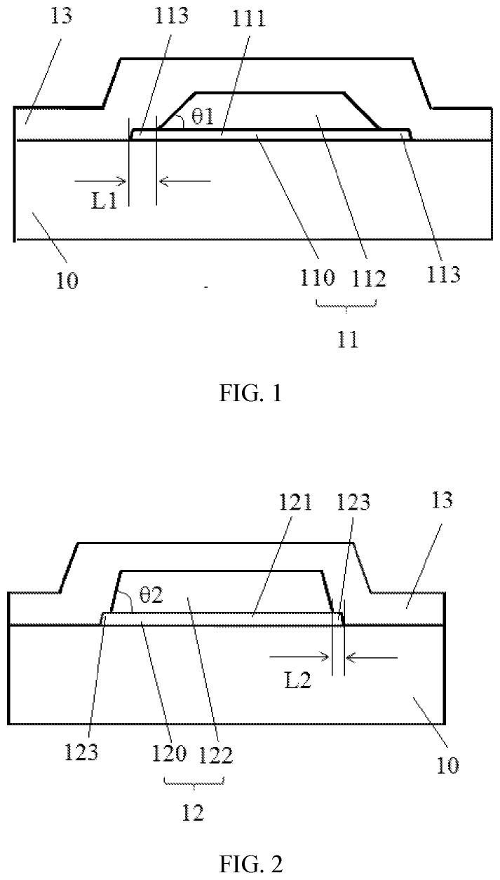

Please refer to FIG. 1. One embodiment of the present invention provides a thin-film transistor (TFT) array substrate, including a glass substrate layer 10 and a metal layer 11 disposed on the glass substrate layer 10, wherein the metal layer 11 includes an insulating layer 13 disposed thereon.

The metal layer 11 includes a barrier metal layer 110 and an electrode barrier layer 112 disposed in a stacked arrangement, wherein the barrier metal layer 110 includes not only a main body portion 111 disposed below the electrode metal layer 112, but also two tail portions 113 disposed on two opposite ends of the main body portion 111 and extending outwardly from the electrode metal layer 112, respectively. Specifically, each of the tail portions 113 of the barrier metal layer 110 has a length between 0.05-0.25 microns (um).

The electrode metal layer 112 has side portions each formed at an inclined angle such that the electrode metal layer 112 is trapezoidal in shape. Specifically, the inclined angle θ1 is preferably between 25 and 50 degrees. The barrier metal layer 110 may be trapezoidal in shape corresponding to that of the electrode metal layer 112, or the barrier metal layer 110 may be rectangular in shape, or may vary according to specific needs, and is not limited thereto.

Furthermore, the metal layer 11 is specifically embodied as a gate layer (i.e. a gate electrode), a gate line, a gate pad, and the like, and may vary according to specific needs, but is not limited thereto. The electrode metal layer 112 is made of aluminum metal or copper metal. The barrier metal layer 110 is preferably made of metal molybdenum (Mo) or an alloy of metal molybdenum. For example, it is a binary alloy of metal molybdenum or a ternary alloy that may vary according to specific needs, and is not limited thereto.

Please refer to FIG. 2. Another embodiment of the present invention provides a TFT array substrate, including a glass substrate layer 10 and a metal layer 12 disposed on the glass substrate layer 10, wherein the metal layer 12 includes an insulating layer 13 disposed thereon.

The metal layer 12 includes a barrier metal layer 120 and an electrode barrier layer 122 disposed in a stacked arrangement, wherein the barrier metal layer 120 includes not only a main body portion 121 disposed below the electrode metal layer 122, but also two tail portions 123 disposed on two opposite ends of the main body portion 121 and extending outwardly from the electrode metal layer 122, respectively. Specifically, each of the tail portions 123 of the barrier metal layer 120 has a length L2 greater than 0 and less than or equal to 0.10 um.

The electrode metal layer 122 has side portions each formed at an inclined angle such that the electrode metal layer 122 is trapezoidal in shape. Specifically, the inclined angle θ2 is preferably between 50 and 90 degrees. The barrier metal layer 120 may be trapezoidal in shape corresponding to that of the electrode metal layer 122, or the barrier metal layer 120 may be rectangular in shape, or may vary according to specific needs, and is not limited thereto.

Furthermore, the electrode metal layer 122 may be embodied as a source/drain layer (SD), a data line, a data pad, and the like. The electrode metal layer 122 is made of aluminum metal or copper metal. The barrier metal layer 120 is preferably made of metal molybdenum (Mo) or an alloy of metal molybdenum. For example, it is a binary alloy of metal molybdenum or a ternary alloy that may vary according to specific needs, and is not limited thereto.

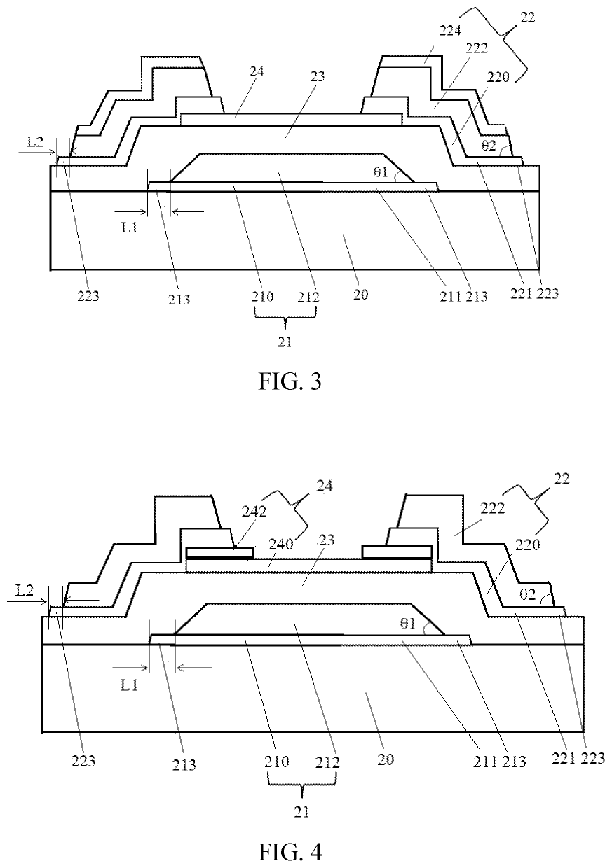

Furthermore, please refer to FIG. 3 showing a TFT array substrate of another embodiment of the present invention. The TFT array substrate includes a glass substrate layer 20, and a gate layer 21, an insulating layer 23, an active layer 24, and a source/drain layer 22 all disposed on the glass substrate layer 20.

Specifically, the gate layer 21 is disposed on the glass substrate layer 20, the insulating layer 23 is disposed on the gate layer 21, and the active layer 24 is disposed on the insulating layer 23. There are two source/drain layers 22 each are disposed on two ends of the active layer 24 and are electrically connected to each other through the active layer 24. The active layer 24 is an indium gallium zinc oxide (IGZO) layer, but is not limited thereto.

Furthermore, the gate layer 21 includes a barrier metal layer 210 and an electrode barrier layer 212 disposed in a stacked arrangement, wherein the barrier metal layer 210 includes not only a main body portion 211 disposed below the electrode metal layer 212, but also two tail portions 213 disposed on two opposite ends of the main body portion 211 and extending outwardly from the electrode metal layer 212, respectively. Specifically, each of the tail portions 213 of the barrier metal layer 210 has a length L1 between 0.05-0.25 um.

The gate layer 21 has side portions each formed at an inclined angle such that the gate layer 21 is trapezoidal in shape. Specifically, the inclined angle θ1 is preferably between 25 and 50 degrees. The barrier metal layer 210 may be trapezoidal in shape corresponding to that of the electrode metal layer 212, or the barrier metal layer 210 may be rectangular in shape, or may vary according to specific needs, and is not limited thereto.

Furthermore, the electrode metal layer 212 is made of aluminum metal or copper metal. The barrier metal layer 210 is preferably made of metal molybdenum (Mo) or an alloy of metal molybdenum. For example, it is a binary alloy of metal molybdenum or a ternary alloy that may vary according to specific needs, and is not limited thereto.

Likewise, the source/drain layer 22 includes a barrier metal layer and an electrode metal layer 222 disposed in a stacked arrangement, but is different from the gate layer 21 in that the barrier metal layer includes a first barrier metal layer 220 and a second barrier metal layer 224 disposed spaced apart from each other in an upper and lower arrangement, wherein the electrode metal layer 222 is sandwiched between the first barrier metal layer 220 and the second barrier metal layer 224 to cooperatively form a sandwich-shaped structure.

Furthermore, the electrode metal layer 222 is made of aluminum metal or copper metal, and the barrier metal layer is preferably made of metal molybdenum (Mo) or an alloy of metal molybdenum. For example, it is a binary alloy of metal molybdenum or a ternary alloy that may vary according to specific needs, and is not limited thereto.

As shown in the figure, the source/drain layer 22 has a stair-like structure according to a specific need. A horizontal part of the stair-like structure has side portions each formed at an inclined angle such that the side portions are trapezoidal in shape. Specifically, the inclined angle θ2 is preferably between 50 and 90 degrees.

The barrier metal layer may be shaped corresponding to a structural shape of the electrode metal layer 222. The first barrier metal layer 220 disposed below the electrode layer 222 includes not only a main body portion 221 disposed below the electrode metal layer 222, but also two tail portions 223 disposed on two opposite ends of the main body portion 221 and extending outwardly from the electrode metal layer 222, respectively. Specifically, each of the tail portions 223 has a length greater than 0 and less than or equal to 0.10 um. A second barrier metal layer 224 disposed on the electrode metal layer 222 is preferably not configured with tail portions extending outward from the electrode metal layer 222, but is not limited thereto.

Furthermore, please refer to FIG. 4 showing a TFT array substrate of another embodiment of the present invention. The TFT array substrate of this embodiment has a structure substantially the same as that of the TFT array substrate as shown in FIG. 3. In order to avoid unnecessary description, the explanation given below is only focused on differences between the two embodiments.

One of the differences between the two embodiments is a structure of an active layer 24. As shown in FIG. 4, the active layer 24 is made of amorphous silicon, so that it is preferably a two-layered structure, wherein one layer 240 is made of amorphous silicon, and the other layer 242 is made of a material doped with amorphous silicon. Specifically, as shown in FIG. 4, the two-layered structure of the active layer 24 is rectangular in shape.

Another one of the differences between the two embodiments is a structure of a source/drain layer 22. Unlike a three-layered structure of the source/drain layer 22 shown in FIG. 3, the source/drain layer 22 shown in FIG. 4 is a two-layered structure including a barrier metal layer 220 and an electrode metal layer 222.

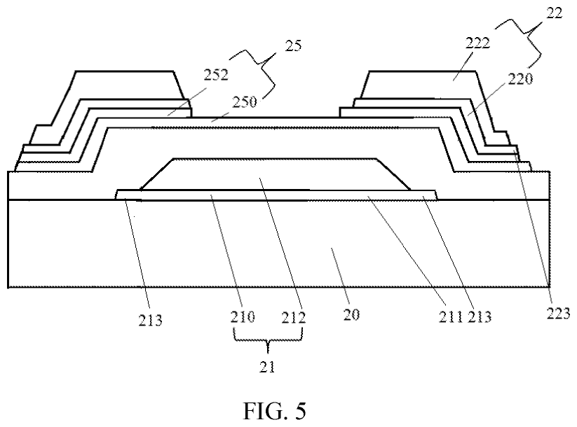

Furthermore, please refer to FIG. 5 showing a TFT array substrate of another embodiment of the present invention. The TFT array substrate of this embodiment has a structure substantially the same as that of the TFT array substrate as shown in FIG. 4. In order to avoid unnecessary description, the explanation given below is only focused on differences between the two embodiments.

The structure of the array substrate as shown in FIG. 5 and FIG. 4 is different in a specific shape of an active layer. Although the active layer of this embodiment is made of amorphous silicon, a layer structure in specific is different between the two embodiments. Specifically, an amorphous silicon material layer 250 of an active layer 25 shown in FIG. 5 is formed into an arch configuration, wherein a material layer 252 doped with amorphous silicon and disposed on the amorphous silicon mater layer 250 is stair-like in shape, and therefore is different from the active layer 24 being rectangular in shape as shown in FIG. 4.

Furthermore, in another aspect, the present invention provides a display panel including the TFT array substrate of the aforementioned embodiments of the present invention.

The present invention provides a TFT array substrate configured with a metal layer including a barrier metal layer and an electrode metal layer, wherein the barrier metal layer includes tail portions having a specific length, and the electrode metal layer includes side portions formed at an inclined angle in a specific range, so that an entire structure of the metal layer is formed into a specific configuration, thereby effectively improving a situation that light leakage occurred at the metal layer structure of the array substrate in a dark state, and increasing product contrast.

The technical scope of the present invention is not limited to the above description, and those skilled in the art can make various modifications and changes to the above embodiments without departing from the technical idea of the present invention, and thus the scope of the present invention should be after the appended claims and their equivalents.

What is claimed is:

1. A thin-film transistor (TFT) array substrate, comprising:
a substrate layer and a metal layer disposed on the substrate layer, wherein the metal layer comprises a first metal layer and a second metal layer disposed on the first metal layer;
wherein the first metal layer comprises a main body portion and a tail portion, wherein the main body portion of the first metal layer is disposed corresponding to the second metal layer in an upper direction, and the tail portion of the first metal layer is disposed on an end of the main body portion of the first metal layer and extends outwardly from the second metal layer.

2. The TFT array substrate of claim 1, wherein the first metal layer is configured as a metal barrier layer, and the second metal layer is configured as a metal electrode layer.

3. The TFT array substrate of claim 2, further comprising a third metal layer disposed on the second metal layer, wherein the third metal layer is configured as a metal barrier layer.

4. The TFT array substrate of claim 1, wherein the tail portion of the first metal layer has a length greater than 0 and less than or equal to 0.25 microns (um).

5. The TFT array substrate of claim 1, wherein the metal layer is a gate layer, wherein the tail portion of the first metal layer has a length between 0.05 um and 0.25 um.

6. The TFT array substrate of claim 1, wherein the metal layer is a gate layer comprising a side portion disposed at an inclined angle between 25 and 50 degrees.

7. The TFT array substrate of claim 1, wherein the metal layer is a source/drain layer, wherein the tail portion of the first metal layer has a length greater than 0 and less than or equal to 0.10 um.

8. The TFT array substrate of claim 1, wherein the metal layer is a source/drain layer comprising a side portion disposed at an inclined angle between 50 and 90 degrees.

9. The TFT array substrate of claim 1, wherein the first metal layer has a thickness greater than 0 and less than or equal to 1000 angstroms, and the second metal layer has a thickness greater than 0 and less than or equal to 8000 angstroms.

10. A display panel, comprising the thin-film transistor (TFT) array substrate of claim 1.
